(19) United States
(12) Patent Application Publication
(10) Pub. No.: US 2025/0277812 A1
(43) Pub. Date: Sep. 4, 2025

(54) TESTING APPARATUS OF PACKAGED MODULES AND ITS MANUFACTURING METHOD

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Chih-Chieh LIAO, HSINCHU CITY (TW); Yu-Min SUN, HSINCHU CITY (TW); Chih-Feng CHENG, HSINCHU CITY (TW)

(21) Appl. No.: 18/937,047

(22) Filed: Nov. 5, 2024

(30) Foreign Application Priority Data
Feb. 29, 2024 (TW) 113107316

(51) Int. Cl. G01R 1/04; G01R 3/00; H05K 1/11; H05K 3/40

(52) U.S. Cl. CPC G01R 1/0441; G01R 3/00; H05K 1/111; H05K 3/4007; H05K 2201/10325

(57) ABSTRACT

A testing apparatus includes a circuit board, a socket and a conductive pad. The circuit board is provided with a plurality of contacts. The socket is mounted on the circuit board and provided with a receiving groove thereon. The conductive pad includes a three-dimensional stepped-stage structure and a plurality of elastic conductive pillars. The three-dimensional stepped-stage structure is received within the receiving groove, and provided with a plurality of annular steps which are arranged as concentric rectangles in sequence. Heights of the annular steps are sequentially modified according to a direction from a center point of the concentric rectangles towards the socket. These elastic conductive pillars are respectively inserted into the three-dimensional stepped-stage structure so as to be arranged separately on the annular steps. Each of the elastic conductive pillars is electrically connected to the packaged module and one of the contacts, respectively.

### CROSS-REFERENCE TO RELATED APPLICATION

This application claims priority to Taiwan Application Serial Number 113107316, filed Feb. 29, 2024, the disclosures of which are incorporated herein by reference in their entireties.

### BACKGROUND

### Field of Invention

The present disclosure relates to a testing apparatus. More particularly, the present disclosure relates to a testing apparatus of packaged modules and its manufacturing method.

### Description of Related Art

In general, a device under test (called DUT hereinafter, e.g., packaged modules) will be put into a test bench during a testing stage, so that both ends of each telescopic probe in the test bench respectively are in contact with a soldering joint of the DUT above and a soldering ball on a circuit board below.

However, when the warpage of the DUT is worsened due to the increasing of the temperature, an operator needs to adjust the height of each telescopic probe, otherwise, defects of poor connection performance will occur between the telescopic probe and the solder ball of the DUT, thereby affecting the test results of the DUT.

Therefore, the above-mentioned technologies obviously still have inconveniences and defects, which are issues that the industry needs to solve urgently.

### SUMMARY

One aspect of the present disclosure is to provide a testing apparatus of packaged modules and its manufacturing method for solving the difficulties mentioned above in the prior art.

In one embodiment of the present disclosure, a testing apparatus for packaged modules includes a circuit board, a socket and a conductive pad. The circuit board is provided with a plurality of contacts. The socket is mounted on the circuit board and provided with a receiving groove thereon. The conductive pad includes a three-dimensional stepped-stage structure and a plurality of elastic conductive pillars. The three-dimensional stepped-stage structure is received within the receiving groove, and provided with a plurality of annular steps which are arranged as concentric rectangles in sequence. Heights of the annular steps are sequentially modified according to a direction from a center point of the concentric rectangles towards the socket. These elastic conductive pillars are respectively inserted into the three-dimensional stepped-stage structure so as to be arranged separately on the annular steps. Each of the elastic conductive pillars is electrically connected to the packaged module and one of the contacts, respectively.

In one embodiment of the present disclosure, a testing apparatus for packaged modules includes a circuit board, a socket and a conductive pad. The circuit board is provided with a plurality of contacts. The socket is mounted on the circuit board and provided with a receiving groove thereon. The conductive pad includes a three-dimensional stepped-stage structure and a plurality of elastic conductive pillars. The three-dimensional stepped-stage structure includes a first rectangular block received within the receiving groove, located above the circuit board and formed with a first rectangular opening, a second rectangular block partially embedded within the first rectangular opening, located above the circuit board and formed with a second rectangular opening, and a third rectangular block partially embedded within the second rectangular opening and located above the circuit board. A thickness of the second rectangular block is between a thickness of the first rectangular block and a thickness of the third rectangular block. The elastic conductive pillars are respectively inserted into the three-dimensional stepped-stage structure so as to be spaced distributed on the first rectangular block, the second rectangular block and the third rectangular block, respectively. Each of the elastic conductive pillars is electrically connected to one of the contacts for being in contact with one of the packaged modules.

In one embodiment of the present disclosure, a manufacturing method of a testing apparatus includes several steps. A circuit board, a socket, a first rectangular block, a second rectangular block and a third rectangular block are provided, and a thickness of the second rectangular block is between a thickness of the first rectangular block and a thickness of the third rectangular block. The socket is mounted on the circuit board so that the socket surrounds a plurality of contacts of the circuit board. The first rectangular block is inserted into a receiving groove of the socket so that a plurality of first elastic conductive pillars inserted within the first rectangular block are respectively contacted with a first part of the contacts. The second rectangular block is inserted into a first opening of the first rectangular block so that a plurality of second elastic conductive pillars inserted within the second rectangular block are respectively contacted with a second part of the contacts. The third rectangular block is inserted into a second opening of the second rectangular block so that a plurality of third elastic conductive pillars inserted within the third rectangular block are respectively contacted with a third part of the contacts. Thus, a three-dimensional stepped-stage structure having a plurality of annular steps which are arranged as concentric rectangles in sequence is formed by the first rectangular block, the second rectangular block and the third rectangular block together.

Thus, through the construction of the embodiments above, the testing apparatus is able to match the warpage outline of the DUT by the three-dimensional stepped-stage structure for reducing the possibilities of poor connection performance between the elastic conductive pillars and the solder balls of the DUT, thereby providing accurate test results.

The above description is merely used for illustrating the problems to be resolved, the technical methods for resolving the problems and their efficacies, etc. The specific details of the present disclosure will be explained in the embodiments below and related drawings.

The above description is only an overview of the technical solution of the present disclosure. In order to understand the technical means of the present disclosure, and implement the technical means according to the content of the description, and in order to make the above and other objects, features and advantages of the present disclosure more obvious and understandable, preferred embodiments are specifically cited below and described in detail with reference to the accompanying drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a perspective view of a testing apparatus according to one embodiment of the present disclosure.

FIG. 2 is a top view of the testing apparatus of FIG. 1.

FIG. 3 is a cross-sectional view taken along a line AA in FIG. 2.

FIG. 4 is an exploded view of the testing apparatus and a first packaged module.

FIG. 5 is an exploded view of a testing apparatus and a second packaged module according to one embodiment of the present disclosure.

FIG. 6 is an exploded view of a conductive pad of a testing apparatus according to one embodiment of the present disclosure.

FIG. 7 is a cross-sectional view of a conductive pad of a testing apparatus according to one embodiment of the present disclosure.

FIG. 8 is a flow chart of a manufacturing method of a testing apparatus according to one embodiment of the present disclosure.

FIG. 9A and FIG. 9B are schematic views of operating process in step 801 of FIG. 8 viewed from the top and the cross-sectional directions, respectively.

FIG. 10A and FIG. 10B are schematic views of operating process in step 802 of FIG. 8 viewed from the top and the cross-sectional directions, respectively.

FIG. 11A and FIG. 11B are schematic views of operating process in step 803 of FIG. 8 viewed from the top and the cross-sectional directions, respectively.

FIG. 12A and FIG. 12B are schematic views of operating process in step 804 of FIG. 8 viewed from the top and the cross-sectional directions, respectively.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

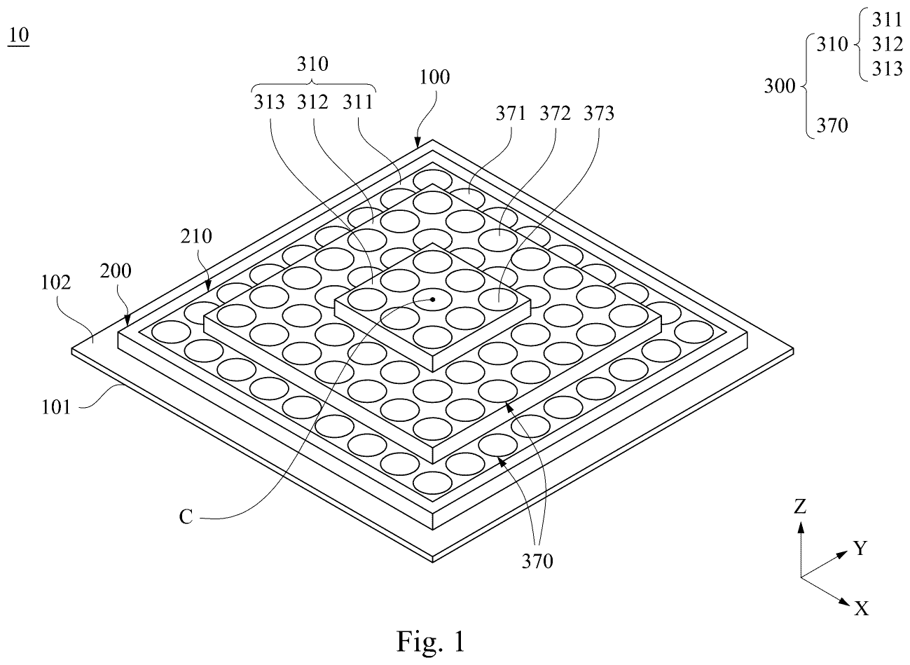

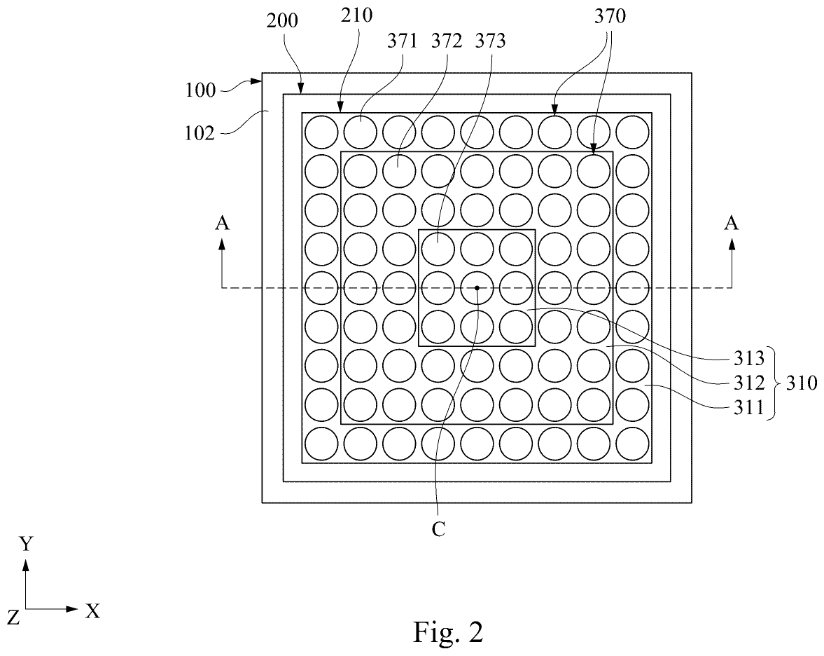

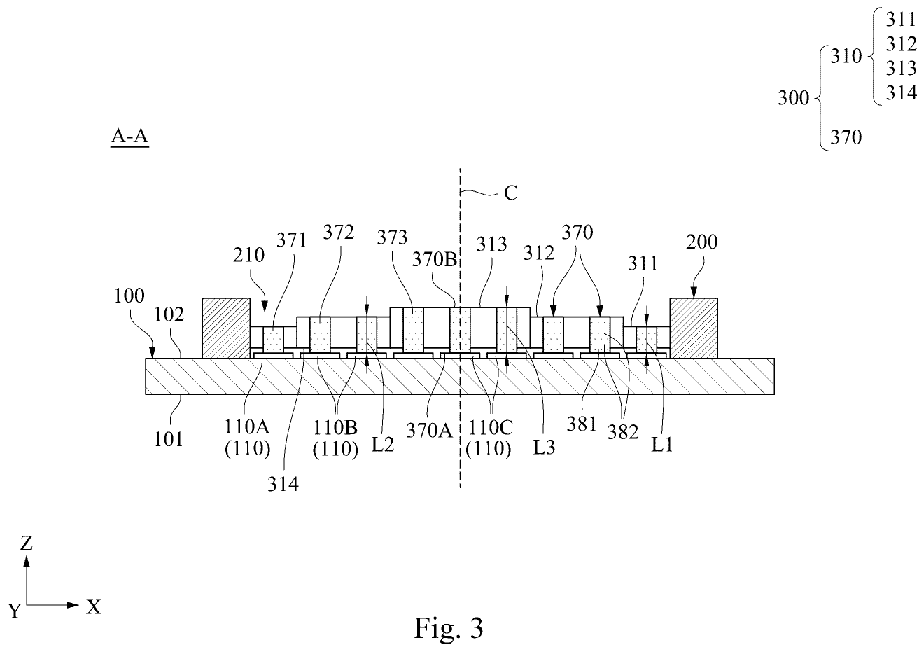

Reference is now made to FIG. 1 to FIG. 3, in which FIG. 1 is a perspective view of a testing apparatus 10 according to one embodiment of the present disclosure. FIG. 2 is a top view of the testing apparatus 10 of FIG. 1. FIG. 3 is a cross-sectional view taken along a line AA in FIG. 2. As shown in FIG. 1 to FIG. 3, in the embodiment, the testing apparatus 10 includes a circuit board 100, a socket 200 and a conductive pad 300. The circuit board 100 is provided with a plurality of contacts 110 (FIG. 3). In this embodiment, the circuit board 100 is a rectangular board with a back surface 101 and a top surface 102 opposite to each other. These contacts 110 are spaced apart on the top surface 102 of the circuit board 100. Furthermore, the contacts 110 are arranged in an array on the top surface 102 of the circuit board 100. However, the present disclosure is not limited thereto. The socket 200 is mounted on the circuit board 100 and provided with a receiving groove 210 thereon. The conductive pad 300 includes a three-dimensional stepped-stage structure 310 and a plurality of elastic conductive pillars 370. The three-dimensional stepped-stage structure 310 is located on the top surface 102 of the circuit board 100 and matchingly received into the receiving groove 210 of the socket 200. The three-dimensional stepped-stage structure 310 has a pyramid or trapezoidal shape, and the three-dimensional stepped-stage structure 310 includes a plurality of annular steps (e.g., a first step 311, a second step 312 and a third step 313). These circular steps are concentric rectangles arranged in sequence. The innermost ring (i.e., third step 313) of these annular steps has a center point C. These annular steps (e.g., the first step 311, the second step 312 and the third step 313) collectively surround the center point C, and heights of the annular steps (e.g., the first step 311, the second step 312 and the third step 313) are sequentially modified according to a direction from the center point C of the concentric rectangles towards the socket 200 (e.g., the outer side of the conductive pad 300). The three-dimensional stepped-stage structure 310 includes, for example, soft materials such as silicone or rubber. However, the present disclosure is not limited thereto. These elastic conductive pillars 370 are spaced distributed on these annular steps (e.g., the first step 311, the second step 312 and the third step 313). In other words, each of these annular steps (e.g., one of the first step 311, the second step 312 and the third step 313) is equipped with several elastic conductive pillars 370, and these elastic conductive pillars 370 are symmetrically distributed on these annular steps (e.g., the first step 311, the second step 312 and the third step 313).

More specifically, in this embodiment, the distribution pattern of these elastic conductive pillars 370 is the same as the distribution pattern of the above-mentioned contacts 110 of the circuit board 100. Each of the elastic conductive pillar 370 (e.g., one of the first elastic conductive pillars 371, second elastic conductive pillars 372 and third elastic conductive pillars 373) is inserted on the three-dimensional stepped-stage structure 310. Each of the elastic conductive pillar 370 extends along a long axis direction (e.g., Z-axis), and is provided with a first end 370A and a second end 370B opposite to each other. The first end 370A of each of the elastic conductive pillars 370 extends outwards from one side (called as a bottom side 314, hereinafter) of the three-dimensional stepped-stage structure 310 facing away from these annular steps, and directly contacts or at least electrically contacts with one of the contacts 110 of the circuit board 100, and one end surface of the second end 370B thereof is flush with one surface of the three-dimensional stepped-stage structure 310 (e.g., the first step 311, the second step 312 and the third step 313).

More specifically, in this embodiment, the three-dimensional stepped-stage structure 310 (e.g., the first step 311, the second step 312 and the third step 313) is in a bulged shape, and the heights of the annular steps (e.g., the first step 311, the second step 312 and the third step 313) are gradually decreased along the direction from the center point C of the concentric rectangles towards the socket 200 (i.e., outer side of the conductive pad 300). The annular steps (e.g., the first step 311, the second step 312 and the third step 313) are only located on one side of the three-dimensional stepped-stage structure 310 facing away from the circuit board 100, however, the present disclosure is not limited thereto. The bottom side 314 of the three-dimensional stepped-stage structure 310 facing away from these annular steps is a plane facing towards the circuit board 100 for being placed on the top surface 102 of the circuit board 100.

For example, these annular steps are sequentially called a third step 313 (i.e., the innermost one of the annular steps), a second step 312 and a first step 311 (i.e., the outermost one of the annular steps) along a direction from the center point C towards the socket 200 (i.e., the outer side of the conductive pad 300). The elastic conductive pillars 370 include one or plural first elastic conductive pillars 371, one or plural second elastic conductive pillars 372 and one or plural third elastic conductive pillars 373. The first elastic conductive pillars 371, the second elastic conductive pillars 372 and the third elastic conductive pillars 373 are arranged sequentially along the direction from the socket 200 (that is, outside the conductive pad 300) towards the center point C. In other words, these first elastic conductive pillars 371 are distributed on the first step 311, and these third elastic conductive pillars 373 are distributed on the third step 313. The length L2 of each of the second elastic conductive pillars 372 is greater than the length L1 of each of the first elastic conductive pillars 371, and shorter than the length L3 of each of the third elastic conductive pillars 373.

Also, in the embodiment, each of the elastic conductive pillars 370 includes a soft cylinder body 381 and a plurality of conductive particles 382. These conductive particles 382 are pre-made in the soft cylinder body 381 and spaced distributed in the soft cylinder body 381. The soft cylinder body 381 includes, for example, soft material such as silicone or rubber. The conductive particles 382 include metals such as copper and aluminum. However, the present disclosure is not limited to this.

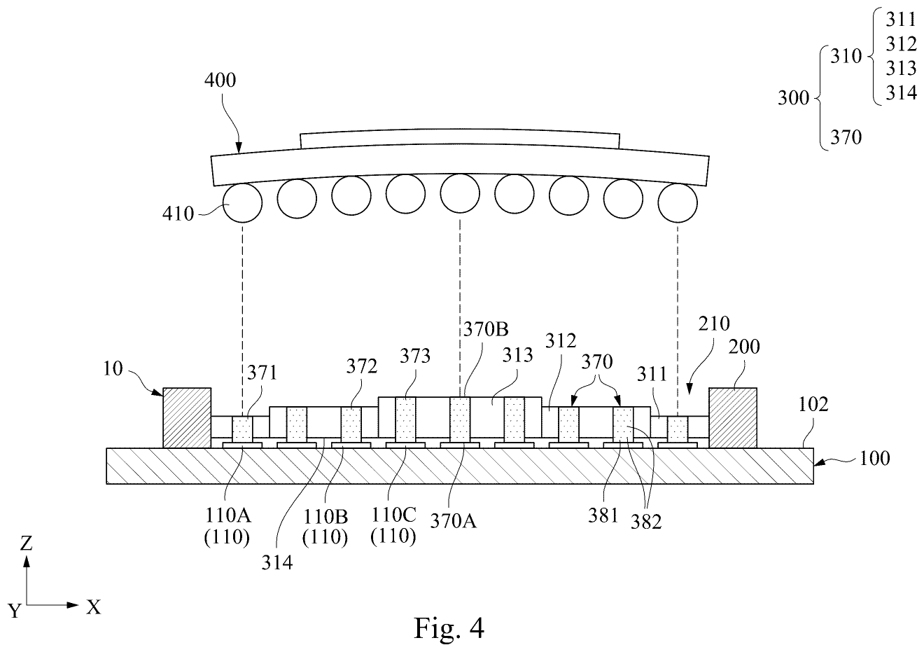

Reference is now made to FIG. 4, in which FIG. 4 is an exploded view of the testing apparatus 10 and a first packaged module 400. As shown in FIG. 4, the testing apparatus 10 of this embodiment is suitable for a first packaged module 400 whose cross-section has a warped shape (i.e., crying curve). Therefore, when a user places the first packaged module 400 into the receiving groove 210 of the socket 200, the annular steps (i.e., the first step 311, the second step 312 and the third step 313) of the three-dimensional stepped-stage structure 310 can match the warpage profile of the first packaged module 400 to be engaged with the first packaged module 400 together, so that the solder balls 410 of the first packaged module 400 can directly contact with the second ends 370B of the above-mentioned elastic conductive pillars 370 one by one.

Next, when the first packaged module 400 starts to be vertically pressed down the three-dimensional stepped-stage structure 310 to enable the bottom side 314 of the three-dimensional stepped-stage structure 310 to face toward the top surface 102 of the circuit board 100, since the three-dimensional stepped-stage structure 310 and the soft cylinder bodies 381 have flexible characteristics, the conductive particles 382 in each of the soft cylinder bodies 381 are close to each other for electrical conduction when being squeezed, thereby achieving electrical conduction between the first packaged module 400 and the circuit board 100. Thus, the possibilities of poor connection performance between each of the elastic conductive pillars 370 and the corresponding solder ball 410 of the first packaged module 400 are reduced, thereby providing accurate test results. In addition, since the bottom side 314 of the three-dimensional stepped-stage structure 310 is flat, the first end 370A of each of the elastic conductive pillars 370 is able to contact with the corresponding contact 110 with a relatively uniform force, thereby preventing displacement and deviation.

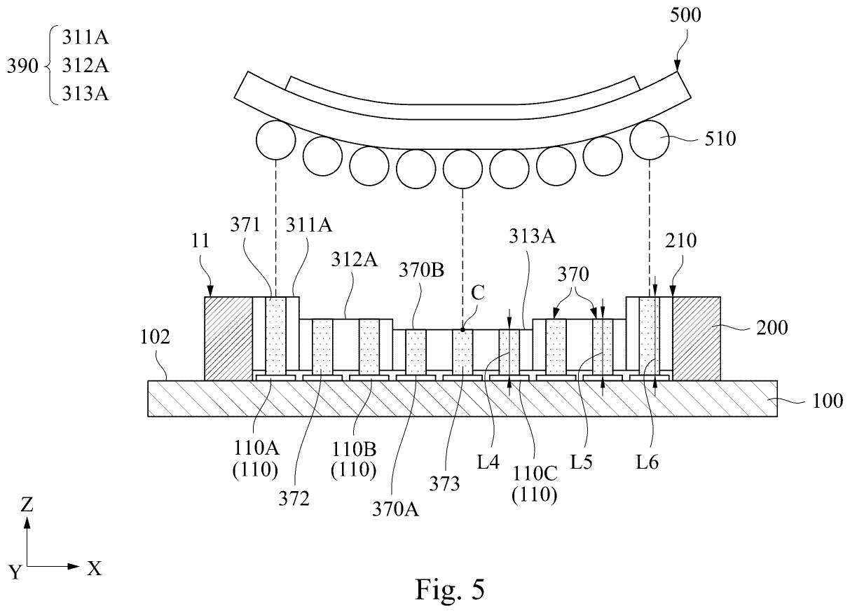

FIG. 5 is an exploded view of a testing apparatus 11 and a second packaged module 500 according to one embodiment of the present disclosure. As shown in FIG. 5, the testing apparatus 11 of this embodiment is substantially the same as the above-mentioned testing apparatus 10, except that the testing apparatus 11 of this embodiment is suitable for a second packaged module 500 whose cross-section has a warped shape (i.e., smiling curve). In this embodiment, the three-dimensional stepped-stage structure 390 is in a sunken shape, and the heights of these annular steps (i.e., the first step 311A, the second step 312A and the third step 313A) are gradually increased along the direction from the center point C thereof towards the socket 200. More specifically, the length L5 of each of the second elastic conductive pillars 372 is greater than the length L4 of each of the first elastic conductive pillars 371 and smaller than the length L6 of each of the third elastic conductive pillars 373.

In this way, when the user places the second packaged module 500 into the receiving groove 210 of the socket 200, the annular steps (i.e., the first step 311A, the second step 312A and the third step 313A) of the three-dimensional stepped-stage structure 390 can match the warpage profile of the second packaged module 500 to be engaged with the second packaged module 500 together, so that the solder balls 510 of the second packaged module 500 can directly contact the second ends 370B of the above-mentioned elastic conductive pillars 370 one by one.

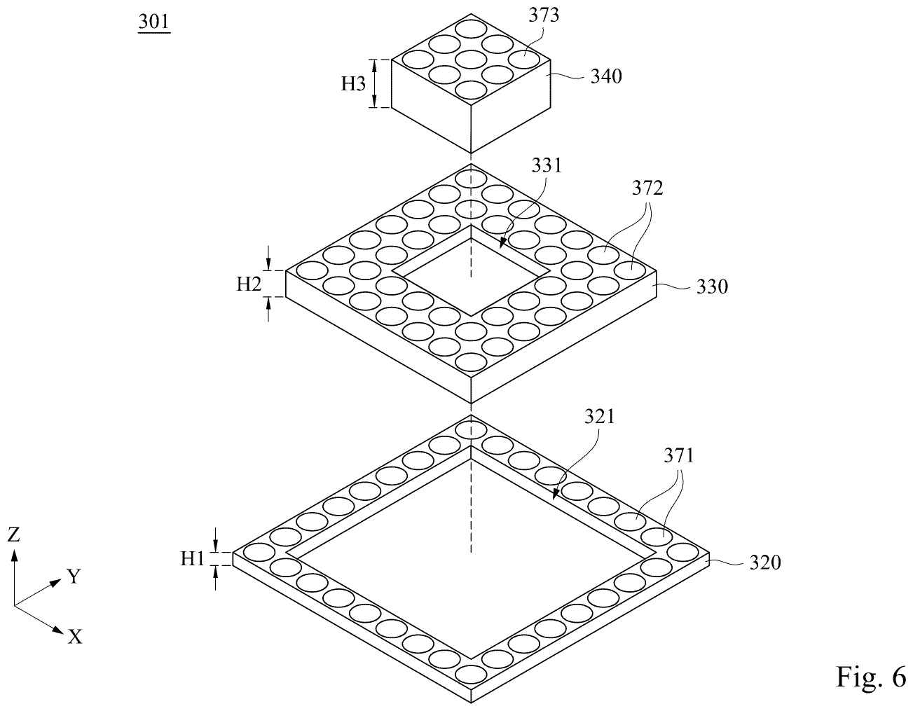

FIG. 6 is an exploded view of a conductive pad 301 of a testing apparatus according to one embodiment of the present disclosure. The testing apparatus of this embodiment is substantially the same as the above-mentioned testing apparatus 10, except that the conductive pad 301 is not integrally formed, but assembled in sequence. In this way, components of corresponding order can be provided in response to changes in size and curvature requirements of the packaged module.

For example, as shown in FIG. 6, the three-dimensional stepped-stage structure 310 includes a first rectangular block 320, a second rectangular block 330 and a third rectangular block 340. The first rectangular block 320 is formed with a first opening 321 (e.g., first rectangular opening) that is located, for example, at a centroid of the first rectangular block 320. These first elastic conductive pillars 371 are embedded into and arranged on the first rectangular block 320 and surround the first opening 321 at intervals. One part of the second rectangular block 330 is embedded within the first opening 321, and the other part thereof extends outwards from the first opening 321. The second rectangular block 330 is formed with a second opening 331 (e.g., second rectangular opening) located, for example, at a centroid of the second rectangular block 330. These second elastic conductive pillars 372 are embedded into and arranged on the second rectangular block 330 and surround the second opening 331 at intervals. One part of the third rectangular block 340 is embedded within the second opening 331, and the other part thereof extends outwards from the second opening 331. These third elastic conductive pillars 373 are embedded into and arranged on the third rectangular block 340.

Refer to FIG. 3 and FIG. 6, the first rectangular block 320 is removably placed into the receiving groove 210 of the socket 200, and placed on the top surface 102 of the circuit board 100 (refer to FIG. 3), and the first rectangular block 320 located in the receiving groove 210 is directly contacted with or at least quite close to the socket 200 (refer to FIG. 3). Specifically, an area of the first rectangular block 320 is equal to an area of the receiving groove 210 (refer to FIG. 3), an area of the second rectangular block 330 is smaller than the area of the first rectangular block 320, larger than an area of the third rectangular block 340, and equal to or substantially equal to an area of the first opening 321, an area of the third rectangular block 340 is equal to an area of the second opening 331, and a thickness H2 of the second rectangular block 330 is greater than a thickness H1 of the first rectangular block 320 and less than a thickness H3 of the third rectangular block 340. However, the present disclosure is not limited to this.

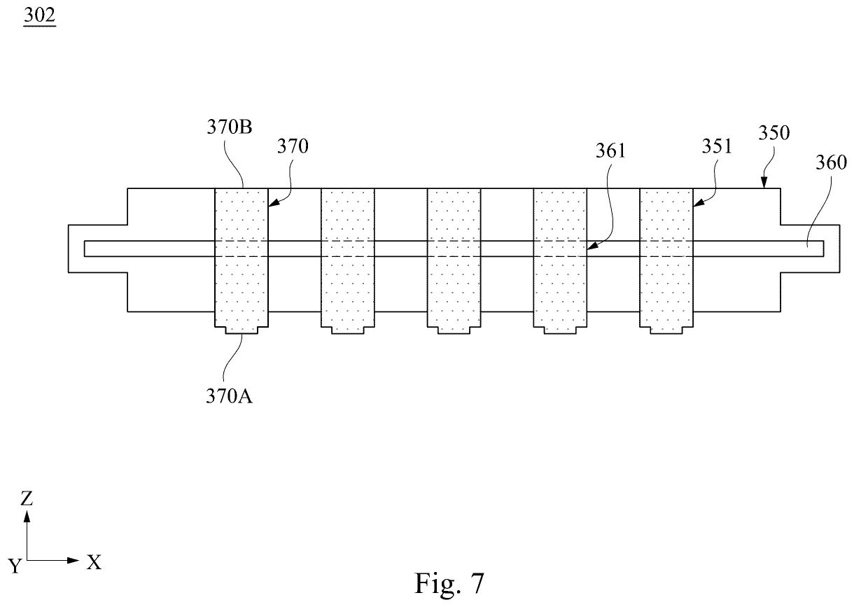

FIG. 7 is a cross-sectional view of a conductive pad 302 of a testing apparatus according to one embodiment of the present disclosure. As shown in FIG. 7, the conductive pad 302 of this embodiment is substantially the same as the above-mentioned conductive pad 300, except that the conductive pad further includes an insulated body 350 and an internal bracket 360. The insulated body 350 is formed with a plurality of first through holes 351 which are spaced distributed. These first through holes 351 are arranged at intervals along a plane direction of the X-Y axis. The internal bracket 360 is embedded within the insulated body 350 so as to support the conductive pad 302 in the receiving groove 210 (FIG. 3). The internal bracket 360 is provided with a plurality of second through holes 361 which are spaced distributed, and the second through holes 361 are arranged at intervals along a plane direction of the X-Y axis. Each of the second through holes 361 is coaxially aligned and connected to one of the first through holes 351. Each of the elastic conductive pillars 370 is in one of the first through holes 351 and one of the second through holes 361. For example, the internal bracket 360 is made of an insulating hard material (such as wood or plastic). It is noted, it mainly describes the internal features of the conductive pad in this embodiment, and does not illustrate the three-dimensional stepped structure shown on its surface of the conductive pad.

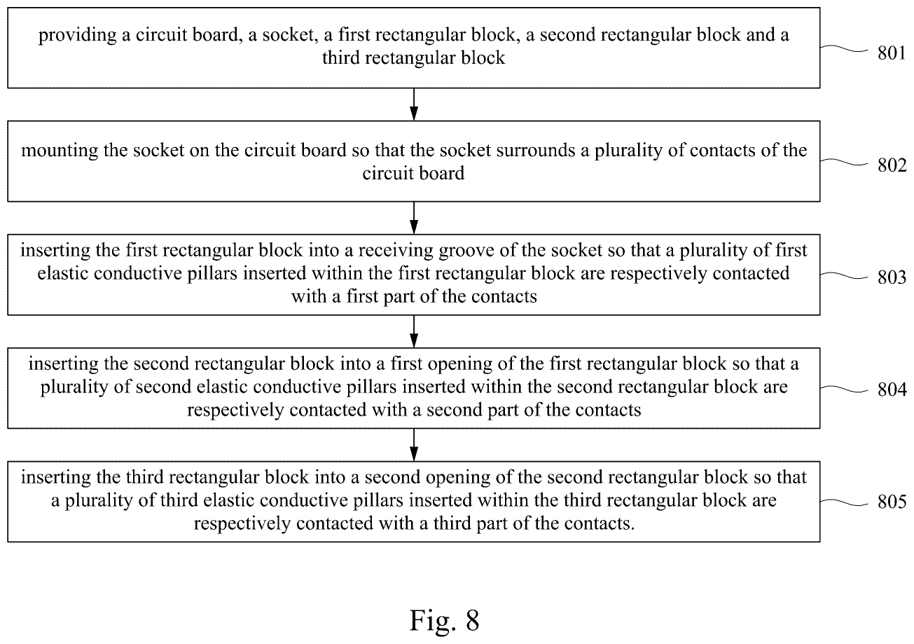

FIG. 8 is a flow chart of a manufacturing method of a testing apparatus according to one embodiment of the present disclosure. As shown in FIG. 8, a manufacturing method of a testing apparatus includes step 801 to step 805. In step 801, a circuit board, a socket, a first rectangular block, a second rectangular block and a third rectangular block are provided. In step 802, the socket is mounted on the circuit board so that the socket surrounds a plurality of contacts of the circuit board. In step 803, the first rectangular block is inserted into a receiving groove of the socket so that a plurality of first elastic conductive pillars inserted within the first rectangular block are respectively contacted with a first part of the contacts. In step 804, the second rectangular block is inserted into a first opening of the first rectangular block so that a plurality of second elastic conductive pillars inserted within the second rectangular block are respectively contacted with a second part of the contacts. In step 805, the third rectangular block is inserted into a second opening of the second rectangular block so that a plurality of third elastic conductive pillars inserted within the third rectangular block are respectively contacted with a third part of the contacts.

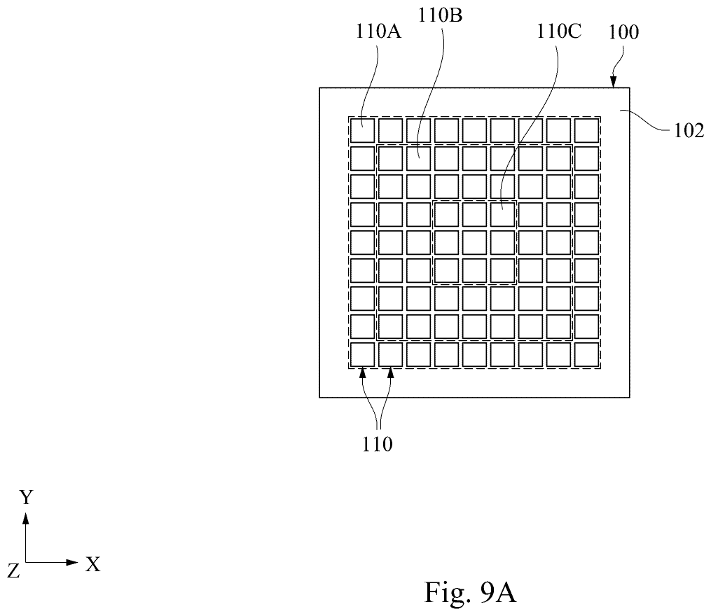

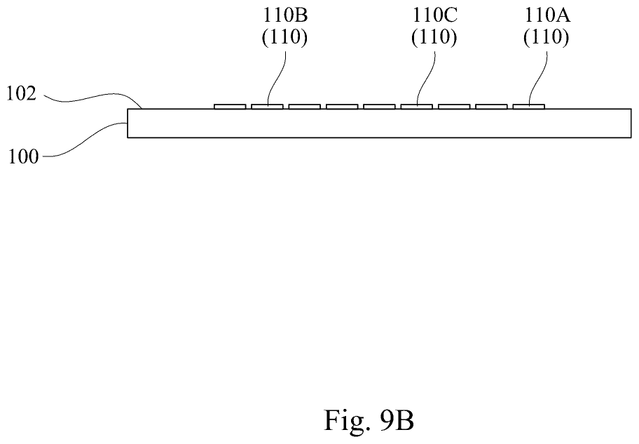

FIG. 9A and FIG. 9B are schematic views of operating process in step 801 of FIG. 8 viewed from the top and the cross-sectional directions, respectively. More specifically, as shown in FIG. 9A and FIG. 9B, the contacts 110 of the circuit board 100 described in step 801 are arranged on the top surface 102 of the circuit board 100 in an array to meet the distribution patterns of solder balls of the packaged module and the elastic conductive pillars.

It is noted, sizes, types and functions of the contacts 110 of the circuit board 100 are not obvious difference. However, for convenience of description, the contacts 110 of the circuit board 100 are divided into a first part 110A, a second part 110B and a third part 110C according to their positions. The first part 110A of the contacts surrounds the second part 110B and the third part 110C of the contacts, and the second part 110B of the contacts surrounds the third part 110C of the contacts. It is noted, the circuit board 100, the socket 200, the first rectangular block 320, the second rectangular block 330 and the third rectangular block 340 described here are the same as the above embodiment, and will not be described again here.

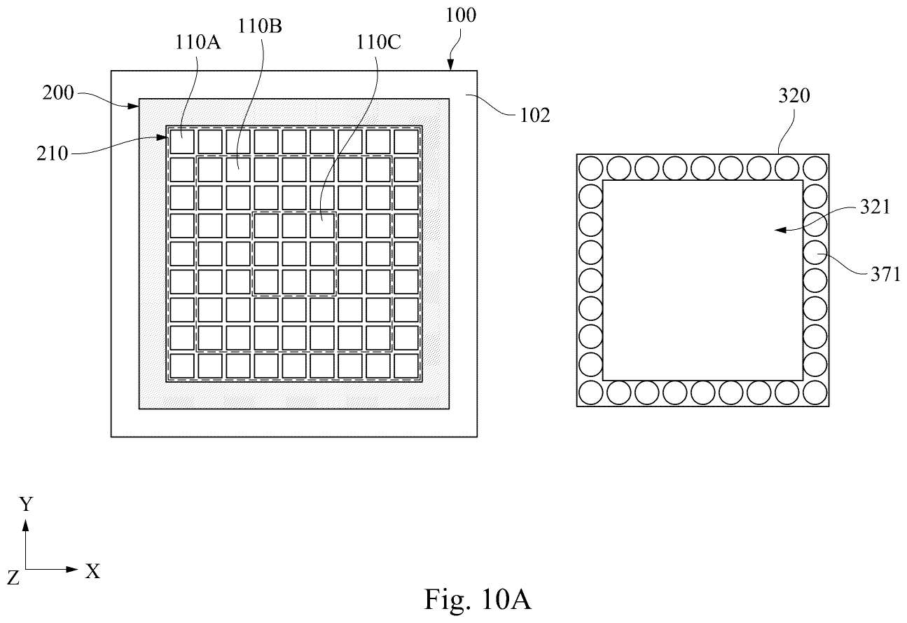

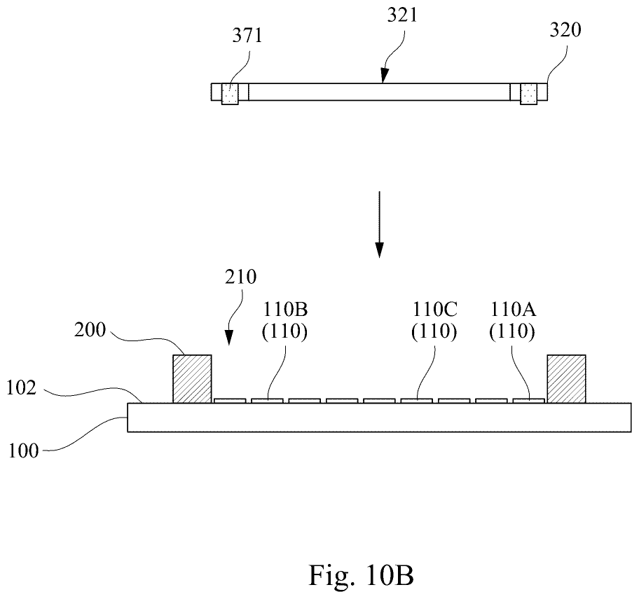

FIG. 10A and FIG. 10B are schematic views of operating process in step 802 of FIG. 8 viewed from the top and the cross-sectional directions, respectively. As shown in FIG. 10A and FIG. 10B, more specifically, in Step 802, the socket 200 is mounted on the top surface 102 of the circuit board 100 so that the socket 200 surrounds all of the contacts 110 (i.e., the first part 110A, the second part 110B and the third part 110C thereof) of the circuit board 100. That is, all of the contacts 110 (i.e., the first part 110A, the second part 110B and the third part 110C thereof) of the circuit board 100 are located in the receiving groove 210 of the socket 200.

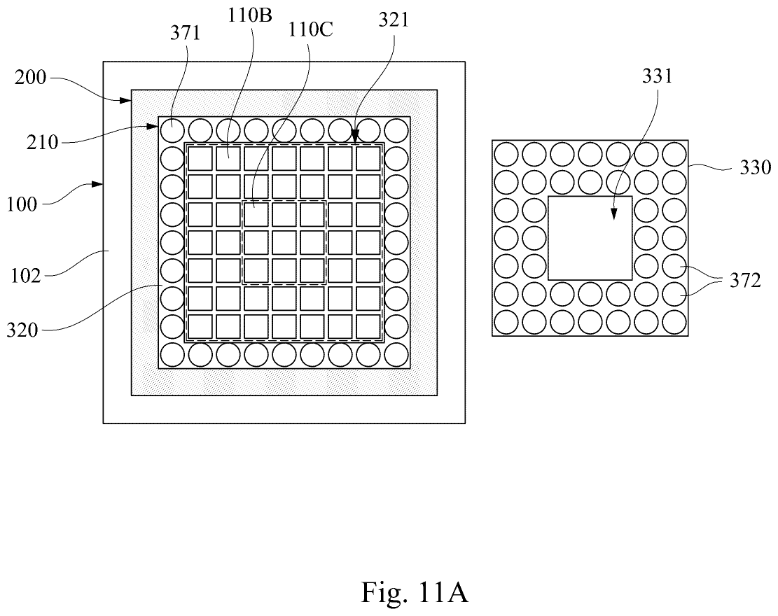

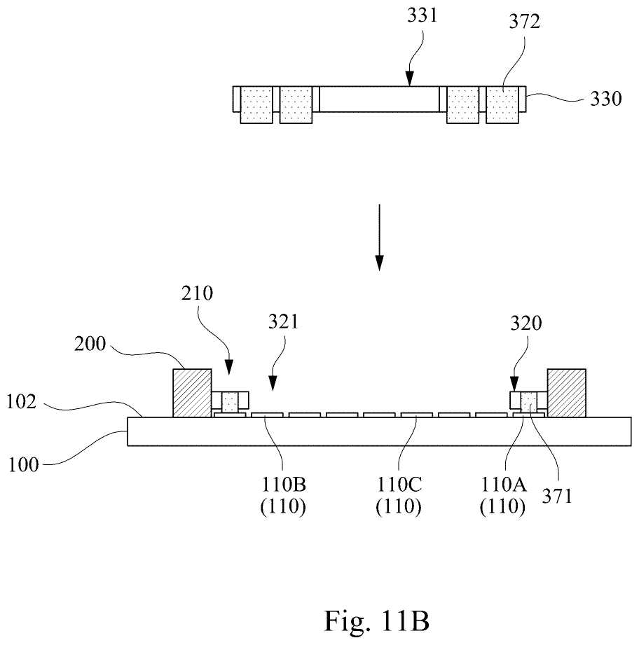

FIG. 11A and FIG. 11B are schematic views of operating process in step 803 of FIG. 8 viewed from the top and the cross-sectional directions, respectively. As shown in FIG. 10A and FIG. 11A, more specifically, in step 803, the first rectangular block 320 is removably placed into the receiving groove 210 of the socket 200, so that the first rectangular block 320 is in contact with the socket 200, and the first elastic conductive pillars 371 are respectively contacted with the first part 110A of the contacts (FIG. 11B). In addition, the second part 110B and the third part 110C of the contacts are all exposed outwards from the first opening 321 of the first rectangular block 320 (see FIG. 11A).

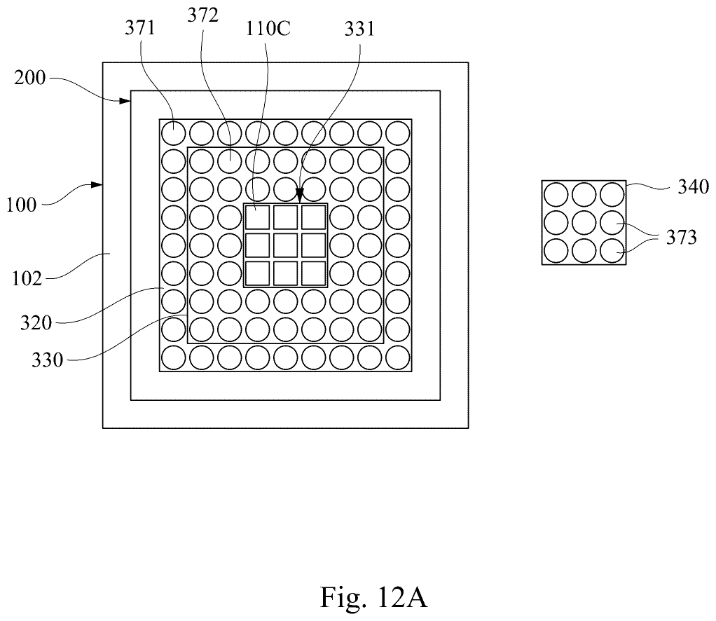

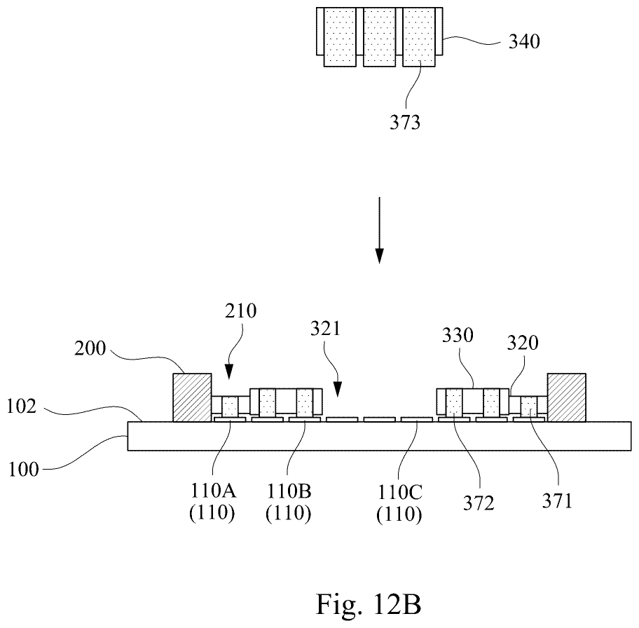

FIG. 12A and FIG. 12B are schematic views of operating process in step 804 of FIG. 8 viewed from the top and the cross-sectional directions, respectively. As shown in FIG. 11A and FIG. 12A, more specifically, in step 804, the second rectangular block 330 is removably inserted into the first opening 321 of the first rectangular block 320, so that the second rectangular block 330 directly contacts with the first rectangular block 320, and the second elastic conductive pillars 372 of the second rectangular block 330 are respectively contacted with the second part 110B of the contacts one by one. In addition, the third part 110C of the contacts is exposed outwards from the second opening 331 of the second rectangular block 330 (FIG. 12A). It is noted, the second rectangular block 330 can be fixed to the first rectangular block 320 through adhesive if necessary.

As shown in FIG. 12A and FIG. 12B, more specifically, in step 805, the third rectangular block 340 is removably inserted into the second opening 331 of the second rectangular block 330, so that the third elastic conductive pillars 373 of the third rectangular block 340 are respectively contacted with the second part 110B of the contacts one by one (FIG. 3). It is noted, the third rectangular block 340 can be fixed to the second rectangular block 330 through adhesive if necessary.

Thus, through the construction of the embodiments above, the testing apparatus is able to match the warpage outline of the DUT by the three-dimensional stepped-stage structure for reducing the possibilities of poor connection performance between the elastic conductive pillars and the solder balls of the DUT, thereby providing accurate test results.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A testing apparatus for packaged modules, comprising:
a circuit board provided with a plurality of contacts;
a socket mounted on the circuit board and provided with a receiving groove thereon;
a conductive pad, comprising:
a three-dimensional stepped-stage structure received within the receiving groove, and provided with a plurality of annular steps which are arranged as concentric rectangles in sequence, wherein heights of the annular steps are sequentially modified according to a direction from a center point of the concentric rectangles towards the socket; and
a plurality of elastic conductive pillars respectively inserted into the three-dimensional stepped-stage structure so as to be arranged separately on the annular steps, and each of the elastic conductive pillars electrically connected to one of the packaged modules and one of the contacts, respectively.

2. The testing apparatus of claim 1, wherein the three-dimensional stepped-stage structure is in a bulged shape, and the heights of the annular steps are gradually decreased along the direction from the center point of the concentric rectangles towards the socket.

3. The testing apparatus of claim 1, wherein the three-dimensional stepped-stage structure is in a sunken shape, and the heights of the annular steps are gradually increased along the direction from the center point of the concentric rectangles towards the socket.

4. The testing apparatus of claim 1, wherein a bottom side of the three-dimensional stepped-stage structure facing away from the annular steps is a plane facing the circuit board.

5. The testing apparatus of claim 1, wherein one end of each of the elastic conductive pillars extends outwards from a bottom side of the three-dimensional stepped-stage structure and electrically contacted with the one of the contacts, one end surface of the other end of each of the elastic conductive pillars is flush with one surface of one of the annular steps for contacting with one soldering ball of the packaged module.

6. The testing apparatus of claim 1, wherein the conductive pad further comprises:
an insulated body formed with a plurality of first through holes which are spaced distributed; and
an internal bracket embedded in the insulated body and provided with a plurality of second through holes which are spaced distributed, and each of the second through holes that is coaxially aligned and connected to one of the first through holes,
wherein each of the elastic conductive pillars is located within one of the first through holes and one of the second through holes together.

7. The testing apparatus of claim 1, wherein the three-dimensional stepped-stage structure comprises a first rectangular block, a second rectangular block and a third rectangular block, the first rectangular block is formed with a first opening, the second rectangular block is formed with a second opening, one part of the second rectangular block is embedded within the first opening, one part of the third rectangular block is embedded within the second opening,
wherein an area of the first rectangular block is equal to an area of the receiving groove, an area of the second rectangular block is smaller than the area of the first rectangular block, larger than an area of the third rectangular block, and equal to an area of the first opening, an area of the third rectangular block is equal to an area of the second opening, and a thickness of the second rectangular block is greater than a thickness of the first rectangular block and less than a thickness of the third rectangular block.

8. The testing apparatus of claim 1, wherein the elastic conductive pillars comprise at least one first elastic conductive pillar, at least one second elastic conductive pillar and at least one third elastic conductive pillar, the at least one third elastic conductive pillar, the at least one second elastic conductive pillar and the at least one first elastic conductive pillar are sequentially arranged along the direction from the center point of the concentric rectangles towards the socket, and the at least one first elastic conductive pillar is located at an outermost one of the annular steps, and the at least one third elastic conductive pillar is located at an innermost one of the annular steps,
wherein a length of the at least one second elastic conductive pillar is between a length of the at least one first elastic conductive pillar and a length of the at least one third elastic conductive pillar.

9. The testing apparatus of claim 1, wherein each of the elastic conductive pillars comprises a soft cylinder body and a plurality of conductive particles which are spaced distributed within the soft cylinder body.

10. A testing apparatus for packaged modules, comprising:
a circuit board provided with a plurality of contacts;
a socket mounted on the circuit board and provided with a receiving groove thereon;
a conductive pad, comprising:
a three-dimensional stepped-stage structure comprising a first rectangular block received within the receiving groove, located above the circuit board and formed with a first rectangular opening, a second rectangular block partially embedded within the first rectangular opening, located above the circuit board and formed with a second rectangular opening, and a third rectangular block partially embedded within the second rectangular opening and located above the circuit board, wherein a thickness of the second rectangular block is between a thickness of the first rectangular block and a thickness of the third rectangular block; and
a plurality of elastic conductive pillars respectively inserted into the three-dimensional stepped-stage structure so as to be spaced distributed on the first rectangular block, the second rectangular block and the third rectangular block, respectively, and each of the elastic conductive pillars electrically connected to one of the contacts for being in contact with one of the packaged modules.

11. The testing apparatus of claim 10, wherein the three-dimensional stepped-stage structure is in a bulged shape, and the third rectangular block, the second rectangular block and the first rectangular block are sequentially decreased in height.

12. The testing apparatus of claim 10, wherein the three-dimensional stepped-stage structure is in a sunken shape, and the third rectangular block, the second rectangular block and the first rectangular block are sequentially increased in height.

13. The testing apparatus of claim 10, wherein a bottom of the three-dimensional stepped-stage structure is a plane facing the circuit board.

14. The testing apparatus of claim 10, wherein one end of each of the elastic conductive pillars extends outwards from a bottom k of the three-dimensional stepped-stage structure to be electrically contacted with the one of the contacts, and the other end of each of the elastic conductive pillars is flush with one surface of one of the third rectangular block, the second rectangular block and the first rectangular block for being in contact with one soldering ball of the packaged module.

15. The testing apparatus of claim 10, wherein the conductive pad further comprises:
an insulated body formed with a plurality of first through holes which are spaced distributed; and
an internal bracket embedded in the insulated body and provided with a plurality of second through holes which are spaced distributed, and each of the second through holes that is coaxially aligned and connected to one of the first through holes,
wherein each of the elastic conductive pillars is located within one of the first through holes and one of the second through holes together.

16. The testing apparatus of claim 10, wherein an area of the first rectangular block is equal to an area of the receiving groove, an area of the second rectangular block is smaller than the area of the first rectangular block, larger than an area of the third rectangular block, and equal to an area of the first rectangular opening, an area of the third rectangular block is equal to an area of the second rectangular opening.

17. The testing apparatus of claim 10, wherein the elastic conductive pillars comprise at least one first elastic conductive pillar inserted into the first rectangular block, at least one second elastic conductive pillar inserted into the second rectangular block, and at least one third elastic conductive pillar inserted into the third rectangular block,
wherein a length of the at least one second elastic conductive pillar is between a length of the at least one first elastic conductive pillar and a length of the at least one third elastic conductive pillar.

18. The testing apparatus of claim 10, wherein each of the elastic conductive pillars comprises a soft cylinder body and a plurality of conductive particles which are spaced distributed within the soft cylinder body.

19. A manufacturing method of a testing apparatus, comprising:
providing a circuit board, a socket, a first rectangular block, a second rectangular block and a third rectangular block, wherein a thickness of the second rectangular block is between a thickness of the first rectangular block and a thickness of the third rectangular block;
mounting the socket on the circuit board so that the socket surrounds a plurality of contacts of the circuit board;
inserting the first rectangular block into a receiving groove of the socket so that a plurality of first elastic conductive pillars inserted within the first rectangular block are respectively contacted with a first part of the contacts;
inserting the second rectangular block into a first opening of the first rectangular block so that a plurality of second elastic conductive pillars inserted within the second rectangular block are respectively contacted with a second part of the contacts; and
inserting the third rectangular block into a second opening of the second rectangular block so that a plurality of third elastic conductive pillars inserted within the third rectangular block are respectively contacted with a third part of the contacts,
wherein a three-dimensional stepped-stage structure having a plurality of annular steps which are arranged as concentric rectangles in sequence is formed by the first rectangular block, the second rectangular block and the third rectangular block together.
